(19) United States
(12) Patent Application Publication
(10) Pub. No.: US 2026/0090054 A1
(43) Pub. Date: Mar. 26, 2026

(54) SEMICONDUCTOR DEVICE WITH FIELD PLATE STRUCTURE

(71) Applicant: Infineon Technologies Austria AG, Villach (AT)

(72) Inventors: Felix Simon Winterer, München (DE); Thomas Künzig, Baldham (DE); Christian Schippel, Dresden (DE); Dirk Priefert, Moers (DE); Andrei Sidelnicov, Dresden (DE)

(21) Appl. No.: 19/324,418

(22) Filed: Sep. 10, 2025

(30) Foreign Application Priority Data
Sep. 26, 2024 (DE) 102024209350.5
Dec. 12, 2024 (DE) 102024137346.6

(51) Int. Cl. H10D 64/00; H03K 17/04; H03K 17/0412; H10D 1/47; H10D 62/10; H10D 86/00

(52) U.S. Cl. CPC H10D 64/112; H03K 17/0406; H03K 17/04123; H03K 17/04126; H10D 1/472; H10D 62/107; H10D 62/126; H10D 86/201

(57) ABSTRACT

A semiconductor device includes a substrate, an insulator layer, and a field plate structure. The substrate has a background doping of a first conductivity type and includes a first doped region of a second conductivity type complementary to the first conductivity type. The insulator layer is formed on a main surface of the substrate. The field plate structure is formed on the insulator layer between the first doped region and an edge structure. The field plate structure has a high-resistive and/or semi-insulating connection with at least one non-floating conductive structure.

### TECHNICAL FIELD

The present disclosure relates to semiconductor devices having a field plate structure. Examples of the present disclosure relate to high voltage integrated circuits (HVICs) with embedded high voltage devices and to power semiconductor devices with lateral termination structures.

### BACKGROUND

Semiconductor dies for power semiconductor devices with vertical load current flow include lateral termination structures for reducing the electric field towards the lateral edge of the semiconductor die. High voltage integrated circuits in CMOS technology (complementary metal oxide semiconductors) often include a low side part operating in a low voltage domain and a high side part operating in a high voltage domain and embedded high voltage device for exchanging signals between the high side part and the low side part. The embedded high voltage device includes a voltage transition region to reduce the electrical field in the lateral direction. Both the lateral termination structures in power semiconductor devices and the voltage transition regions in high voltage integrated circuits define the breakdown voltage of the semiconductor device. Often, field plate structures shape the electric field in the lateral termination structures and the voltage transition regions to avoid critical field peaks.

There is a constant need to improve the long-term stability of device parameters in semiconductor devices with field plate structures.

### SUMMARY

A semiconductor device includes a substrate, an insulator layer, and a field plate structure. The substrate has a background doping of a first conductivity type and includes a first doped region of a second conductivity type complementary to the first conductivity type. The insulator layer is formed on a main surface of the substrate. The field plate structure is formed on the insulator layer between the first doped region and an edge structure. The field plate structure has a high-resistive and/or semi-insulating connection with at least one non-floating conductive structure. The high-resistance and/or semi-insulating connection facilitates slow transport of charge carriers to and/or from the field plate structure. The charge in the field plate structure can slowly adapt to charges that accumulate and disappear over time in passivation layers and/or a mold material formed over the field plate structure, and that can result in a slowly varying breakdown voltage of the semiconductor device in the absence of the high-resistance and/or semi-insulating connection. The combination of the field plate structure with the charge shielding layer improves the shielding on long time-scales while the combination has only little influence on short time-scales like switching events.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 is a schematic vertical cross-sectional view of a portion of a semiconductor device with a field plate structure and a high-resistance and/or semi-insulating connection of the field plate structure in accordance with an embodiment.

FIGS. 2A, 2B, 2C and 2D include vertical cross-sectional views of portions of three semiconductor devices with a field plate structure and various high-resistance and/or semi-insulating connections of the field plate structure in accordance with embodiments.

FIG. 3 is a schematic vertical cross-sectional view of a portion of a semiconductor device with a charge shielding layer in direct contact with a contact structure for a first doped region and an edge structure in accordance with an embodiment.

FIGS. 4A, 4B and 4C include vertical cross-sectional views of portions of three semiconductor devices with a charge shielding layer in direct contact with various field plate structures in accordance with embodiments.

FIG. 5 is a schematic vertical cross-sectional view of a portion of a semiconductor device with a field plate structure formed above a voltage transition structure in accordance with an embodiment.

FIGS. 6A, 6B and 6C include vertical cross-sectional views of portions of three semiconductor devices with a field plate structure formed above various voltage transition structures in accordance with embodiments.

FIG. 7 is a schematic horizontal cross-sectional view of a semiconductor device with a voltage transition structure formed along a lateral outer surface of a semiconductor die in accordance with an embodiment related to power semiconductor devices.

FIG. 8 is a schematic horizontal cross-sectional view of a semiconductor device with a high voltage device including an embedded voltage transition structure in accordance with an embodiment related to HVICs.

FIG. 9 is a schematic horizontal cross-sectional view of a semiconductor device with a voltage transition structure and a field plate structure with two ring portions formed along a lateral outer surface of a semiconductor die in accordance with an embodiment related to power semiconductor devices.

FIG. 10 is a schematic horizontal cross-sectional view of a semiconductor device with a high voltage device including an embedded voltage transition structure and a field plate structure with two ring portions in accordance with an embodiment related to HVICs.

FIG. 11 is a schematic vertical cross-sectional view of a portion of a semiconductor device with a field plate structure formed above a variation of lateral doping region and with a charge shielding layer connected to contact structures on both sides of the voltage transition region in accordance with an embodiment.

FIG. 12 is a schematic vertical cross-sectional view of a portion of a semiconductor device with a field plate structure having a multitude of laterally separated field rings in accordance with an embodiment.

FIG. 13 is a schematic vertical cross-sectional view of a portion of a semiconductor device with silicon-on-insulator (SOI) configuration and a field plate structure having a plurality of laterally separated field ring in accordance with an embodiment.

FIG. 14 is a schematic vertical cross-sectional view of a portion of a semiconductor device with SOI configuration and a field plate structure having a plurality of laterally separated field rings with tile portions in another metallization layer in accordance with an embodiment.

FIG. 15 is a schematic block diagram of a gate driver circuit with BJTs and MOSFETs for passing differential data signals from a high-side part to a low-side part and from the low-side part to the high-side part in accordance with an embodiment.

### DETAILED DESCRIPTION

The terms “having”, “containing”, “including” and the like are open-ended, and the terms indicate the presence of certain structures, elements or features but do not preclude the presence of additional elements or features. The articles “a”, “an” and “the” include both the plural and singular, unless the context clearly indicates otherwise.

The terms “signal-connected” and “electrically coupled” include a permanent low-resistive ohmic connection between electrically connected elements, for example a direct contact between the concerned elements or a low-resistive connection via a metal and/or heavily doped semiconductor material, but do not preclude the presence of further passive and/or active elements in the signal path between the “signal-connected” or “electrically coupled” elements. For example, the further elements may include resistors, resistive conductor lines, capacitors and/or inductors, transistors, semiconductor diodes, Schottky diodes, transformers, opto-couplers and other.

The term “power semiconductor device” refers to semiconductor devices with a high voltage blocking capability of at least 30 V, for example 48 V, 100 V, 600 V, 1.6 kV, 3.3 kV or more and with a nominal on-state current or forward current of at least 200 mA, for example 1 A, 10 A or more.

The term “vertical power semiconductor device” refers to power semiconductor devices with a vertical load current flow between a first load electrode on a front side of a semiconductor die and a second load electrode on the opposite side, wherein a thickness of the semiconductor die in the vertical direction is typically less than a horizontal extension of the semiconductor die.

An ohmic contact describes a non-rectifying electrical junction between two conductors, e.g., between a semiconductor material and a metal. The ohmic contact has a linear or approximately linear current-voltage (I-V) curve in the first and third quadrant of the I-V diagram as with Ohm's law.

Ranges given for physical dimensions include the boundary values. For example, a range for a parameter y from a to b reads as a≤y≤b. The same holds for ranges with one boundary value like “at most” and “at least”.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

Two adjoining doping regions in a semiconductor layer form a semiconductor junction. Two adjoining doping regions of the same conductivity type and with different dopant concentrations form a unipolar junction, e.g., an n/n+ or p/p+ junction along a boundary surface between the two doping regions. At the unipolar junction a dopant concentration profile orthogonal to the unipolar junction may show a step or a turning point, at which the dopant concentration profile changes from being concave to convex, or vice versa. Two adjoining doping regions of complementary conductivities form a pn junction.

The Figures illustrate relative doping concentrations by indicating “−” or “+” next to the doping type “n” or “p”. For example, “n−” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

The examples described herein provide a semiconductor device that may include a substrate, an insulator layer and a field plate structure. The substrate has a background doping of a first conductivity type and includes a first doped region of a second conductivity type complementary to the first conductivity type. The insulator layer is formed on a main surface of the substrate. The field plate structure is formed on the insulator layer between the first doped region and an edge structure, wherein the field plate structure has a high-resistive and/or semi-insulating connection with at least one non-floating conductive structure.

The substrate may be a semiconducting substrate in which the doped regions of a power semiconductor device are formed, e.g., a single-crystalline silicon substrate. Alternatively, the substrate may be the semiconducting base substrate of a semiconductor-on-insulator (SOI) device. A main surface at a front side of the substrate and an opposite back surface are formed in parallel horizontal planes. A normal to the main surface defines a vertical direction orthogonal to the main surface. The first conductivity type may be n conductivity and the second conductivity type p conductivity. Alternatively, the first conductivity type may be p conductivity and the second conductivity type n conductivity.

The first doped region may extend from the main surface into the substrate and may form a pn junction with a substrate base portion of the substrate, wherein the substrate base portion contains only the background doping. The edge structure may include a second doped region extending from the main surface into the substrate. The first doped region and the second doped region may have the same conductivity type or complementary conductivity types.

For SOI devices, e.g., HVICs, the first doped region and the second doped region may have the same conductivity type and a device-internal termination may be formed in the substrate between the first doped region and the second doped region. In at least one lateral direction, the second doped region may be formed at a comparatively large distance to a lateral outer surface of the substrate and further semiconductor elements may be formed between the second doped region and the lateral outer surface.

For a power semiconductor device with vertical current flow and lateral edge termination, the second doped region may form a channel stopper region extending along or next to the lateral outer surface of the substrate. The channel stopper region is configured to suppress a charge carrier flow from/to the lateral outer surface of the substrate and may have the same conductivity type as and a higher doping than the substrate base portion. In the absence of a channel stopper region, the lateral outer surface may form the edge structure.

The insulator layer may be a homogenous layer or a layer stack with two or more sublayers of different material composition and/or structure. The insulator layer may include silicon oxide, e.g., a thermally grown silicon oxide and/or deposited silicon oxide, a layer of silicon nitride and/or silicon oxynitride, and/or a silicate glass. The insulator layer may be formed directly on the main surface.

The field plate structure may be formed directly on the insulator layer. Alternatively, a semiconductor layer, one or more metallization planes and a corresponding number of interlayer dielectrics may be formed between the insulator layer and the field plate structure in a vertical direction orthogonal to the main surface. The field plate structure may include one or more laterally separated field plate portions of a same material composition. The field plate portions may be equidistant. Each field plate portion may be a homogenous structure or may include two or more horizontal sub-layers of different material composition and/or internal structure. Each field plate portion may include heavily doped polycrystalline silicon, an elementary metal, a metal alloy, and/or a metal compound.

At least one of the field plate portions, a majority of the field plate portions, or all of the field plate portions have a high-resistive and/or semi-insulating connection to one, two, or more non-floating conductive structures. The non-floating conductive structure may be a conductive structure having a non-floating potential when the semiconductor device is in operation and an active semiconductor element, a passive voltage divider, or, via a component terminal, an external device supplies a potential to the non-floating conductive structure. Each of the non-floating conductive structures may include a contact structure forming an ohmic contact with a doped region in the substrate and/or a doped device region in a semiconductor layer formed on the insulator layer. Alternatively, the non-floating conductive structure may be or include an auxiliary conductor receiving a potential from an active semiconductor element, a passive voltage divider, or, via a component terminal, from an external device.

During operation, charge carriers can accumulate in passivation layers and/or in a mold material formed over the main surface of the substrate and/or the field plate structure at a large time scale. The amount of accumulated charge can change with time. Without high-resistive and/or semiconducting connection, the fluctuating charge can change characteristic parameters of the semiconductor device like breakdown voltage and/or leakage current over time.

The high-resistive and/or semi-insulating connection enables a charge carrier transport to the field plate structure that is sufficient to allow a slow self-adjustment of a mirror charge building up in the field plate structure over time. To this purpose, the high-resistive and/or semi-insulating connection facilitates significantly better transport of electrons and/or holes than a silicon oxide layer, a silicon nitride layer, a polyimide layer, or a conventional mold material. The high-resistive and/or semi-insulating connection facilitates significantly less transport of electrons and/or holes than a metal layer such that a leakage current from/to the first doped region through the high-resistive and/or semi-insulating connection is smaller than or in the same order of magnitude as parallel leakage paths. The charge carrier build-up is several orders of magnitude slower than a switching time of the semiconductor device.

In combination with the charge shielding layer, a mirror charge in the field plate structure compensates the accumulated charges in the passivation layer and/or mold material to a high degree at any time and reduces the effect of the accumulated charge on the device characteristics. On the other hand, the electric separation of the field plate portions from the non-floating conductive structure and other conductive structures is still sufficiently strong so that the field plate portions can be regarded as electrically floating when the semiconductor device operates in accordance with the intended use.

According to an embodiment, the non-floating conductive structure may include a contact structure, wherein the contact structure forms an ohmic contact with one of the first doped regions and a second doped region, wherein the second doped region may be part of the edge structure.

According to another embodiment, the non-floating conductive structure may include a contact structure, wherein the contact structure forms an ohmic contact with a doped device region of a semiconductor layer formed on the insulator layer.

According to an embodiment, the high-resistive and/or semi-insulating connection may include a charge shielding layer in direct contact with the field plate structure and the non-floating conductive structure.

The charge shielding layer is high-resistive and/or semi-insulating. In addition to the charge shielding layer, the high-resistive and/or semi-insulating connection may include one or more low-resistive sections electrically connected in series between the charge shielding layer and the non-floating conductive structure. The low-resistive sections may include a metal structure, e.g. a metal line,

The conductivity of the charge shielding layer may be a function of the electric field to which the charge shielding layer is exposed or may be independent of the electric field. For example, the material of the charge shielding layer may have a specific resistance greater than 1 Ωcm, for example, greater than 10⁴ Ωcm at a temperature of 25 degree Celsius and may be metallic or semiconducting in nature. The specific resistance may increase (metal-like) or decrease (semiconductor-like) with increasing temperature. The charge shielding layer may be a homogenous layer or a layer stack of two or more sublayers of different material composition and/or structure. The charge shielding layer may include or consist of a layer of high-purity semiconductor material, e.g., amorphous silicon a-Si, diamond-like carbon DLC or silicon-rich silicon nitride SiSiN with a higher silicon content than stoichiometric Si₃N₄. The charge shielding layer may be a one-part structure enabling a comparatively slow charge carrier transport between the field plate portions and at least one of the first doped regions, the second doped region in the edge structure, and the auxiliary conductor on a very small scale, which may be lower than or in the same order of magnitude as other leakage currents to or from the first doped region.

According to an embodiment, the charge shielding layer may be formed directly on the field plate structure.

According to an embodiment, the semiconductor device may further include an insulating passivation layer formed on the charge shielding layer.

The passivation layer is formed from one insulator material or more insulator materials and may include, e.g., an organic insulator material such as a polyimide. The passivation layer may be formed directly on the charge shielding layer or may be separated from the charge shielding layer, e.g., by a barrier layer. The material of the passivation layer may be prone to generate, absorb and/or release ions. A mold material may embed the semiconductor die. The mold material may be prone to generate, absorb and/or release ions when the semiconductor device operates under ambient conditions.

According to an embodiment, the semiconductor device may include a separation layer separating the charge shielding layer and the passivation layer.

The separation layer may be a homogenous layer or may include two or more sub-layers of different materials, e.g., a silicon oxide layer, a silicon nitride layer, and/or a silicon oxynitride layer. The separation layer may form a diffusion barrier that prevents humidity and/or ions to diffuse from the passivation layer and the mold material into the charge shielding layer and beyond. The separation layer increases the distance between the metal field plate portions and the passivation layer and reduces the electric field in portions of the passivation layer, in particular in the vicinity of the top edges of the field plate portions.

According to an embodiment, the field plate structure may include a metal portion and the charge shielding layer may be formed directly on the metal portion.

The field plate structure may include two or more laterally separated field plate portions, with each field plate portion including a part of the metal portion. The metal portion and other metal contact structures of the semiconductor device may be formed from the same deposited metal layer. The charge shielding layer can be patterned together with a subsequently deposited passivation layer.

According to an embodiment, the field plate structure may include a polysilicon portion formed from doped polycrystalline silicon and the charge shielding layer may be formed directly on the polysilicon portion.

The field plate structure may include two or more laterally separated field plate portions, with each field plate portion including a part of the polysilicon portion. Compared to metal field plate portions, polycrystalline field plate portions may be patterned with higher precision. Each part of the polycrystalline portion may have a uniform width, a uniform vertical extension and uniform doping. Deposition and patterning of a polycrystalline silicon layer to form the polycrystalline field plate portions adds only low extra effort to the manufacturing process.

According to an embodiment, the field plate structure may include a polycrystalline portion formed at a distance from the main surface and a metal portion formed in direct contact with the polycrystalline portion at a side of the polycrystalline portion opposite to the substrate, wherein the charge shielding layer is formed directly on the metal portion.

The field plate structure may include two or more laterally separated field plate portions, with each field plate portion including a part of the metal portion and a part of the polysilicon portion. The parts of the polycrystalline portion may be formed from laterally separated sections of a planar polycrystalline layer. A second interlayer dielectric may be formed on the laterally separated sections of the planar polycrystalline layer. Openings in the second interlayer dielectric may expose the separated parts of the polycrystalline portion. A deposited metal fills the openings. A layer formed from the deposited metal is patterned to form laterally separated parts of the metal portion. The charge shielding layer may cover the surface of the metal portion over the second interlayer dielectric and therefore can be patterned together with the passivation layer without an additional lithography process. Since the charge shielding layer is not deposited until after the metal layers and interlayer dielectrics are deposited and patterned, the process control for the charge shielding layer is relaxed.

According to an embodiment, the semiconductor device may further include a voltage transition structure formed in the substrate between the first doped region and the edge structure, wherein the voltage transition structure is configured to reduce a maximum electric field in the substrate when a voltage is present between the first doped region and the edge structure.

The voltage transition structure reduces a maximal electric field strength occurring in a portion of the substrate between the first doped region and the edge structure, for example, when a voltage is applied between the first doped region and the second doped region or between the first doped region and a rear side electrode formed on a rear side of the substrate opposite to the main surface. The voltage transition structure may smooth the curvature of a depletion zone (charge space zone) developing along the pn junction between the substrate base portion and the first doped region.

The voltage transition structure may be a one-part structure that is in lateral contact with the first doped region. Such one-part structure may form a junction termination region with a lower maximum dopant concentration than the first doped region. For vertical high voltage semiconductor devices, the junction termination region is part of the lateral edge termination of the semiconductor device and resembles a junction termination extension JTE of the first doped region.

Alternatively, the one-part structure may be a variation of lateral doping region in which the dopant concentration decreases in lateral direction with increasing distance to the first doped region. For vertical power semiconductor devices, the variation of lateral doping region is part of the lateral edge termination of the semiconductor device and resembles a variation of lateral doping VLD of the first doped region.

Alternatively or in combination with a junction termination region or a variation of lateral doping region, the voltage transition structure may include one, two, or more guard regions of the second conductivity type laterally separated from each other, the first doped region, and the edge structure. Each of at least some or all of the guard regions may be formed in the vertical projection of one of the field plate portions, wherein the guard region and the corresponding field plate portion are capacitively coupled to each other.

According to an embodiment, the voltage transition structure may laterally surround the first doped region.

For a vertical power semiconductor device, the voltage transition structure may be formed in an edge termination region that laterally separates the first doped region from the lateral outer surface of the substrate in all lateral directions. For a SOI device, the voltage transition structure may be formed in a device transition region laterally separating a low side part of the SOI device form a high side part, wherein both the low side part and the high side part include digital and/or analog circuits, and the reference potentials of the high side part and the low side part differ from each other by more than 60V, e.g., more than 600V in operation.

According to an embodiment, the field plate structure may laterally surround the first doped region. For a vertical power semiconductor device, the field plate portions of the field plate structure may be formed in the edge termination region that laterally separates the first doped region from the lateral outer surface of the substrate in all lateral directions. For a SOI device, the field plate portions are formed in the device transition region.

According to an embodiment, the edge structure may include a lateral outer surface of the substrate. The semiconductor device may be a vertical power semiconductor device, e.g. a high voltage (HV) semiconductor diode, a bipolar junction transistor (BJT), a junction field effect transistor (JFET), or a MOSFET (metal oxide semiconductor field effect transistor) in the usual meaning including insulated gate field effect transistors (IGFETs) with polysilicon gate electrodes, e.g. a silicon MOSFET or a silicon carbide (SiC) MOSFET, or an insulated gate bipolar transistor (IGBT). When the semiconductor device is an HV semiconductor diode, the first doped region forms an anode region. When the semiconductor device is a MOSFET or IGBT, the first doped region forms the body region for the transistor cells, wherein the body region separates the transistor cell source regions from a common drain/drift structure. The insulator layer can be formed directly on the main surface of the substrate and forms an interlayer dielectric vertically separating the substrate from a first metallization layer in which the field plate structure may be formed.

According to another embodiment, the semiconductor device may further include a semiconductor layer formed on the insulator layer and a first interlayer dielectric formed on the semiconductor layer, wherein the field plate structure is formed over the first interlayer dielectric.

The field plate structure may be formed directly on the first interlayer dielectric. Alternatively, further metallization layers and interlayer dielectrics may be formed between the field plate structure and the first interlayer dielectric. The edge structure may include a second doped region of the second conductivity type. In at least one lateral direction, digital and/or analog circuits may be formed between the lateral outer surface and an outer edge of the field plate structure. The semiconductor device is an HVIC, e.g., a controller for power factor correction or a gate driver circuit.

According to an embodiment, the semiconductor device may further include a first metallization structure formed directly on the first interlayer dielectric and a second interlayer dielectric formed directly on the first metallization structure, wherein the field plate structure may include a first portion formed from a portion of the first metallization structure and a second portion formed on the second interlayer dielectric. The field plate structure may be formed in a second metallization plane.

According to an embodiment, the field plate structure may include a plurality of laterally separated field plate portions, the first metallization layer may include a plurality of laterally separated tile portions, wherein each tile portion is electrically connected with at least one of the field plate portions. The tile portions may increase the horizontal area covered by the field plate structure and may improve the shielding effect of the field plate structure.

According to an embodiment, the tile portions may be formed in gaps between the field plate portions. Each tile portion may span across at least 50% of the gap between the two neighboring metal field plate portions. For example, each tile portion may completely span the gap between the two neighboring field plate portions of the tile portion, wherein a lateral width of the tile portion may be greater than the lateral distance between the two neighboring field plate portions on both sides of the gap. Each vertical line intersecting the main surface between the first doped region and the edge structure may intersect one tile portion and/or one of the field plate portions.

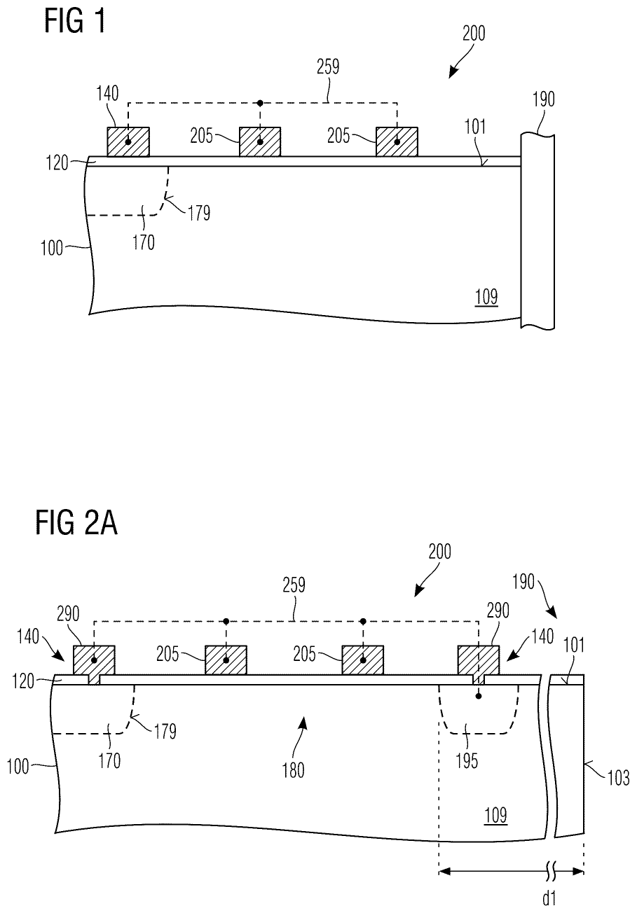

FIG. 1 shows a semiconductor die with a substrate 100 from single-crystalline silicon. A main surface 101 at a front side of the substrate 100 and an opposite back surface 102 are formed in parallel horizontal planes. A normal to the main surface defines a vertical direction orthogonal to the main surface 101.

The substrate 100 has a background doping of a first conductivity type. A first doped region 170 of a second conductivity type complementary to the first conductivity type extends from the main surface 101 into the substrate 100. A substrate base portion 109 of the substrate 100 contains only the background doping. The first doped region 170 and the substrate base portion 109 form a pn junction 179.

An insulator layer 120 is formed directly on the main surface 101. The insulator layer 120 includes silicon oxide, e.g., a thermally grown silicon oxide and/or deposited silicon oxide, a layer of silicon nitride, a layer of silicon oxynitride, and/or a layer of a silicate glass.

An edge structure 190 is formed at a lateral distance to the first doped region 170. The edge structure 190 may be or include a lateral outer surface of the semiconductor die, a doped region extending from the main surface 101 into the substrate 100, an insulating trench structure extending from the main surface 101 into the substrate 10, a conductive structure formed on the insulator layer 120, a conductive structure formed on the main surface 101 of the substrate 100 or a conductive structure extending from the main surface 101 into the substrate 100.

A field plate structure 200 is formed on the insulator layer 120 between the first doped region 170 and the edge structure 190. The field plate structure 200 includes laterally separated field plate portions 205 of a same material composition. Each field plate portion 205 is a homogenous structure from heavily doped polycrystalline silicon, an elementary metal, a metal alloy, and/or a metal compound.

A high-resistive and/or semi-insulating connection 259 structurally connects the field plate structure 200 with a non-floating conductive structure 140 formed directly on the main surface 101 or at a distance from the main surface 101. The high-resistive and/or semi-insulating connection 259 may include one or more low-resistive sections electrically connected in series with one or more high-resistive and/or semi-insulating sections.

During operation, charge carriers can accumulate in layers over the field plate structure 200 at a large time scale. The amount of accumulated charge can vary with time. The high-resistive and/or semi-insulating connection 259 enables the charge on the field plate structure 200 to follow the permanently changing charge in the layers above the field plate structure 200 and to continuously mirror the amount of charge accumulated there, so that characteristic parameters of the semiconductor device such as breakdown voltage and/or leakage current remain stable over the long term. On the other hand, the charge transport through the high-resistive and/or semi-insulating connection 259 is slow enough to be without significant influence on the switching behavior.

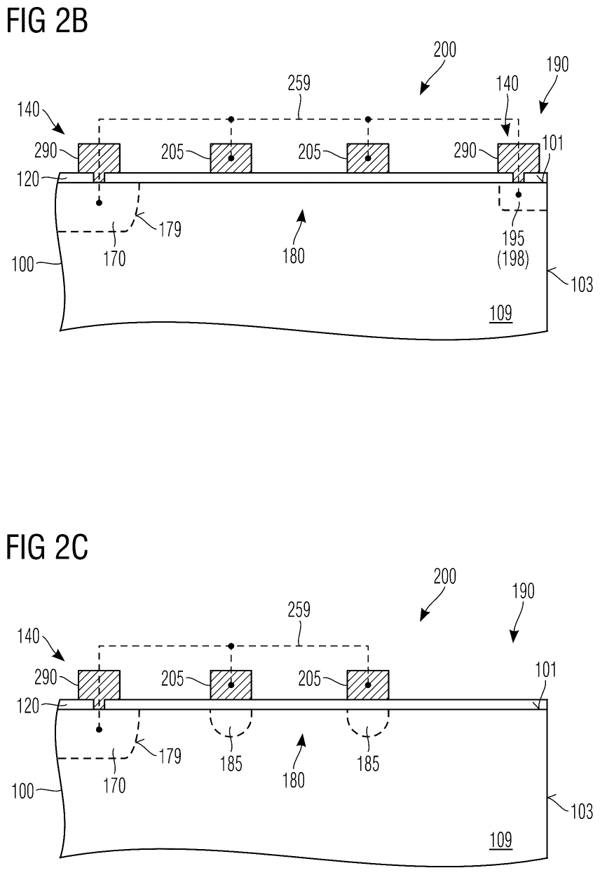

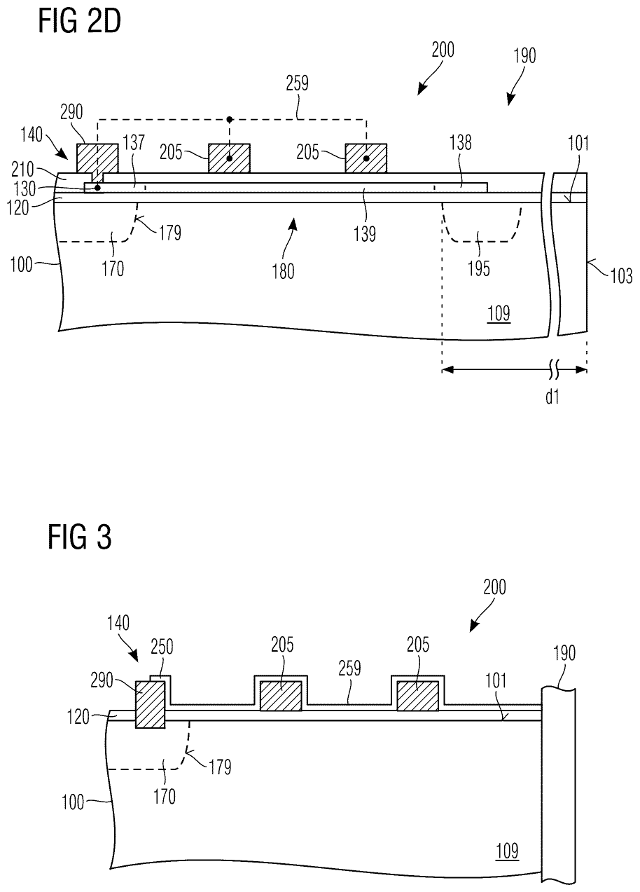

In FIG. 2A, the edge structure 190 includes a second doped region 195 extending from the main surface 101 into the substrate 100. The second doped region 195 has the second conductivity type. The second doped region 195 and the substrate base portion 109 form a further pn junction. The field plate structure 200 forms part of a voltage transition structure 180 formed between the first doped region 170 and the second doped region 195. The voltage transition structure 180 forms a device-internal termination between a low side part and a high side part of a HVIC. In at least one lateral direction, a distance d1 between an inner edge of the second doped region 195 oriented to the first doped region 170 to a lateral outer surface 103 of the substrate 100 can be comparatively large and further semiconductor elements can be formed between the inner edge of the second doped region 195 and the lateral outer surface 103.

The non-floating conductive structure 140 includes a first contact structure 290 forming an ohmic contact with the first doped region 170 and a second contact structure 290 forming an ohmic contact with the second doped region 195. The high-resistive and/or semi-insulating connection 259 structurally connects the field plate structure 200 with the contact structures 290.

In FIG. 2B the edge structure 190 includes a second doped region 195 extending along the lateral outer surface 103 of the substrate 100 from the main surface 101 into the substrate 100. The second doped region 195 has the first conductivity type. The second doped region 195 and the substrate base portion 195 form a unipolar junction. The field plate structure 200 forms part of a voltage transition structure 180 formed between the first doped region 170 and the second doped region 195. The voltage transition structure 180 forms an edge termination between a functional part of the semiconductor die and the lateral outer surface 103. No further semiconductor elements are formed between the outer edge of the second doped region 195 and the lateral outer surface 103.

The second doped region 195 forms a channel stopper region 198 suppressing a charge carrier flow from/to the lateral outer surface 103 of the substrate 100 and may have the same conductivity type as and a higher doping than the substrate base portion 109.

The non-floating conductive structure 140 includes a first contact structure 290 forming an ohmic contact with the first doped region 170 and a second contact structure 290 forming an ohmic contact with the second doped region 195. The high-resistive and/or semi-insulating connection 259 structurally connects the field plate structure 200 with the contact structures 290.

In FIG. 2C, the lateral outer surface 103 forms the edge structure 190. In addition to a field plate structure 200 with two laterally separated field plate portions 205, the voltage transition structure 180 includes guard regions 185 of the second conductivity type. The guard regions 185 are laterally separated from each other. Each guard region 185 may be formed directly below a field plate portion 205, wherein the insulator layer 120 separates the guard regions 185 from the field plate portions 205. Each guard region 185 is capacitively coupled to a corresponding one of the field plate portions 205.

The non-floating conductive structure 140 includes a contact structure 290 forming an ohmic contact with the first doped region 170. The high-resistive and/or semi-insulating connection 259 structurally connects the field plate structure 200 with the contact structures 290.

In FIG. 2D, the edge structure 190 includes a first doped region 170 and a second doped region 195 extending from the main surface 101 into the substrate 100. Similar as in FIG. 2A, a field plate structure 200 forms part of a voltage transition structure 180 formed between the first doped region 170 and the second doped region 195. The voltage transition structure 180 forms a device-internal termination between a low side part and a high side part of a HVIC. A semiconductor layer 130 is formed on the insulator layer 120. A first interlayer dielectric 210 is formed on the semiconductor layer 130. A field plate structure 200 is formed on the first interlayer dielectric 210 between the first doped region 170 and the second doped region 195.

The non-floating conductive structure 140 includes a contact structure 290 forming an ohmic contact with a doped device region 137 in the semiconductor layer 130. A further doped device region 138 is formed in the semiconductor layer 130. The doped device regions 137, 138 may be anode region and cathode region of a HV semiconductor diode, source region and drain region of an MOSFET or JFET, or emitter region and collector region of a BJT or IGBT. The high-resistive and/or semi-insulating connection 259 structurally connects the field plate structure 200 with the contact structure 290.

The non-floating conductive structure 140 includes a contact structure 290 forming an ohmic contact with the first doped region 170. The high-resistive and/or semi-insulating connection 259 structurally connects the field plate structure 200 with the contact structure 290.

FIG. 3 shows a metal contact structure 290 extending from the front side into the first doped region 170. A charge shielding layer 250 is formed directly on the field plate structure 200 and on sections of the insulator layer 120 between the field plate portions 205.

The material of the charge shielding layer 250 has a specific resistance greater than 1 Ωcm, for example, greater than 10⁴ Ωcm at a temperature of 25 degree Celsius and is metallic or semiconducting in nature, wherein the specific resistance may increase with increasing temperature as for metals or decrease with increasing temperature as for semiconductors. The charge shielding layer 250 is a silicon-rich silicon nitride SiSiN with a higher silicon content than stoichiometric Si₃N₄.

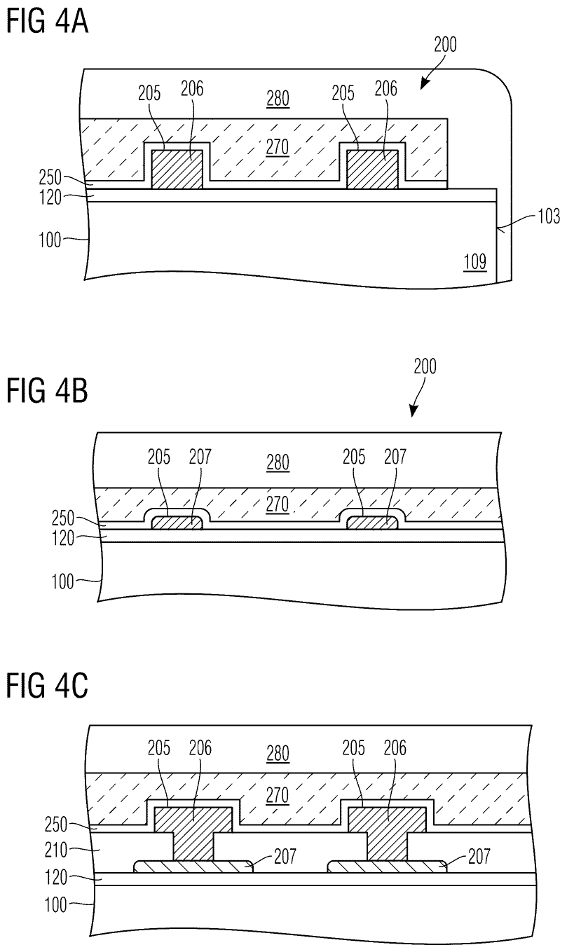

FIG. 4A, FIG. 4B and FIG. 4C show a passivation layer 270 formed on the charge shielding layer 250. The passivation layer 270 fills the gaps between the field plate portions 205 and may have a planar surface at the front side.

The passivation layer 270 contains one or more fully insulating (not semi-insulating) insulator materials, e.g., a silicate glass or an organic insulator material such as a polyimide. The passivation layer 270 may be formed directly on the charge shielding layer 250 or may be separated from the charge shielding layer 250, e.g., by a separation layer or barrier layer. The material of the passivation layer 270 may be prone to generate, absorb and/or release ions. The material of the passivation layer 270 has a higher specific resistance than the material of the charge shielding layer 250. At a temperature of 25 degree Celsius, the specific resistance of the material of the passivation layer 270 is at least one order of magnitude higher than the specific resistance of the material of the charge shielding layer 250.

A mold material 280 is formed on the passivation layer 270 and partially encapsulates the semiconductor die. The mold material 280 may include a meltable organic resin, such as epoxy resin, non-melting inorganic filler materials, catalysts to accelerate the cure reaction, a mold release material allowing the organic resin to come out of a mold, pigments, flame retardants, adhesion promoters, ion traps and/or stress relievers. The mold material may be prone to generate, absorb and/or release ions when the semiconductor device operates under ambient conditions.

In FIG. 4A, the field plate structure 200 includes only a metal portion 206 forming the field plate portions 205. The metal portion 206 forms the laterally separated field plate portions 205 directly on the insulator layer 120. The charge shielding layer 250 is formed directly on the metal portion 206.

In FIG. 4B, the field plate structure 200 includes only a polysilicon portion 207 formed from doped polycrystalline silicon. The polysilicon portion 207 forms the laterally separated field plate portions 205 directly on the insulator layer 120. The charge shielding layer 250 is formed directly on the polysilicon portion 207. Other than with spiral-shaped field plate structures, the charge conduction properties of the shielding structure including the polysilicon portion 207 and the charge shielding layer 250 are adjusted via the thickness and the specific conductivity of the charge shielding layer. The etch process defining the field plate structure 200 from a deposited polysilicon layer and/or a sacrificial oxide process may round the upper edges of the polysilicon field plate portions 205 to reduce the maximum electric field.

In FIG. 4C the field plate structure 200 includes a polycrystalline portion 207 with laterally separated sections formed directly on the insulator layer 120. A first interlayer dielectric 210 covers the polysilicon portion 207 and fills the gaps between the laterally separated sections of the polysilicon portion 207. A metal portion 206 with laterally separated sections is formed on the first interlayer dielectric 210. A through-via section of each laterally separated section of the metal portion 206 extends through first interlayer dielectric 210 to a section of the polysilicon portion 207. The charge shielding layer 250 is formed directly on the metal portion 206. Each field plate portion 205 includes a section of the metal portion 206 including a through-via portion, and a section of the polysilicon portion 207. Since the charge shielding layer 250 is formed after the topmost metal plane, the charge shielding layer 250 can be patterned together with the passivation layer 270.

FIG. 5 shows a voltage transition structure 180 formed in the substrate 100 between the first doped region 170 and the edge structure 190. The voltage transition structure 180 reduces a maximum electric field in the substrate 100 when a voltage is present between the first doped region 170 and the edge structure 190.

The voltage transition structure 180 may form part of a device-internal termination between a low side part and a high side part of an HVIC or part of a lateral edge termination of a power semiconductor device.

The voltage transition structure 180 includes one or more differently defined doped regions of the conductivity type of the first doped region 170, e.g. a JTE, a VLD region, and/or guard regions.

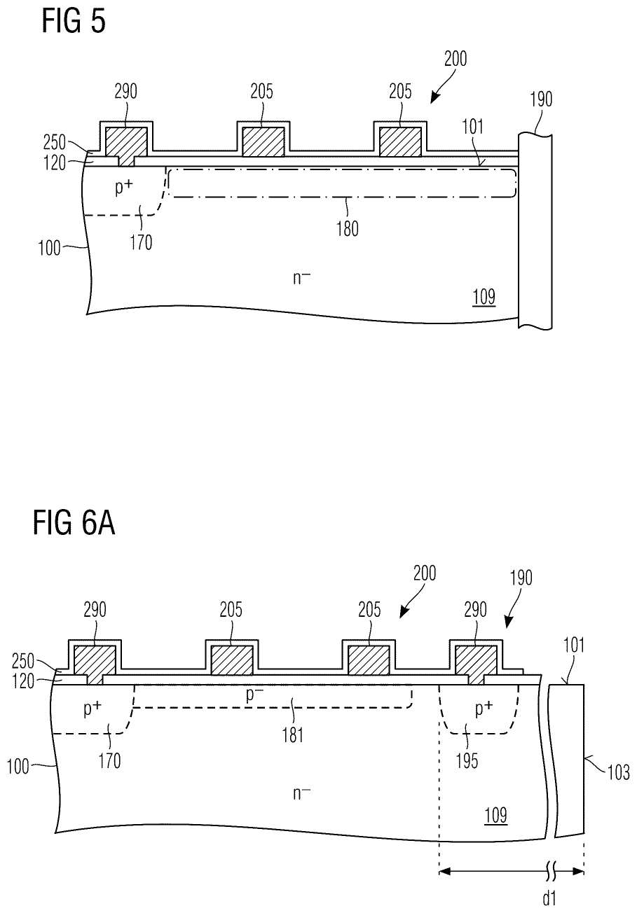

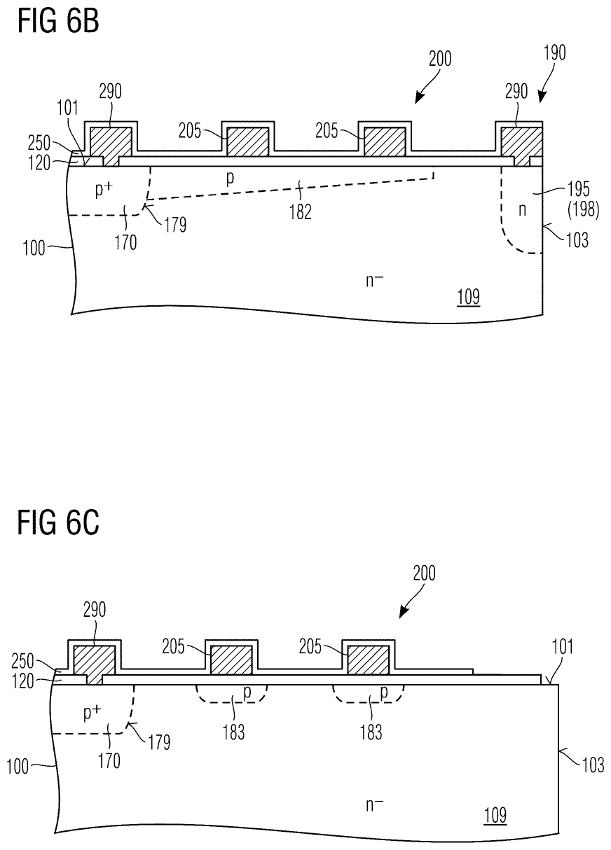

FIG. 6A shows a portion of a HVIC with a first doped region 170 formed in a first voltage domain region and a second doped region 195 in a second voltage domain region of a substrate 100. The first voltage domain region is a first one of the low-side part and the high-side part. The second voltage domain region is the second one of the low-side part of the high-side part. In at least one lateral direction, a distance d1 between the inner edge of the second doped region 195 to a lateral outer surface 103 of the substrate 100 is large enough that logic circuits and/or analog circuits are formed between the inner edge of the second doped region 195 and the lateral outer surface 103. An insulator layer 120 is formed on a main surface 101 at a front side of the substrate 100. Metal contact structures 290 formed on the insulator layer 120 include through-via sections. The through-via sections extend through the insulator layer 120 and form ohmic contacts with the first doped region 170 and the second doped region 195. A field plate structure 200 with laterally separated field plate portions 205 is formed on the insulator layer 120 between the contact structures 290. A charge shielding layer 250 allow a modest charge carrier transport between the field plate portions 205 and the contact structures 290.

A junction termination region 181 with a lower maximum dopant concentration than the first doped region 170 extends in the vertical direction from the main surface 101 into the substrate 100 and in the lateral direction from the first doped region 170 towards the second doped region 195 beyond the outermost field plate portion 205 closest to the second doped region 195. A vertical extent of the junction termination region 181 is constant over a greater part of the lateral extent of the junction termination region 181.

FIG. 6B shows a portion of a power semiconductor device with a first doped region 170 formed in a central region of a substrate 100. A second doped region 195 formed in a peripheral region of the substrate 100 in direct contact with a lateral outer surface 103 of the substrate 100 forms a channel stopper region 198. An insulator layer 120 is formed on a main surface 101 at a front side of the substrate 100. Metal contact structures 290 formed on the insulator layer 120 include through-via sections. The through-via sections extend through the insulator layer 120 and form ohmic contacts with the first doped region 170 and the second doped region 195. A field plate structure 200 with laterally separated field plate portions 205 is formed on the insulator layer 120 between the contact structures 290.

A variation of lateral doping region 182 extends in the vertical direction from the main surface 101 into the substrate 100 and in the lateral direction from the first doped region 170 towards the second doped region 195 beyond the outermost field plate portion 205 closest to the second doped region 195. A vertical extent of the variation of lateral doping region 182 and the dopant concentration in the variation of lateral doping region 182 decrease in the lateral direction with increasing distance to the first doped region 170.

In FIG. 6C, no metal contact structure is formed between the outermost field plate portion 205 closest to the lateral outer surface 103 and the lateral outer surface 103. A weakly doped substrate base portion 195 may extend along the lateral outer surface 103 from the main surface 101 down to the back surface. Laterally separated guard regions 183 of the second conductivity type extend between the first doped region 170 and the lateral outer surface 103 of the substrate 100 from the main surface 101 into the substrate 100. Each guard region 183 is formed directly below one of the field plate portions 205. A vertical projection of a guard region 183 into the plane of the main surface 101 and a vertical projection of the associated field plate portion 205 into the plane of the main surface 101 overlap each other.

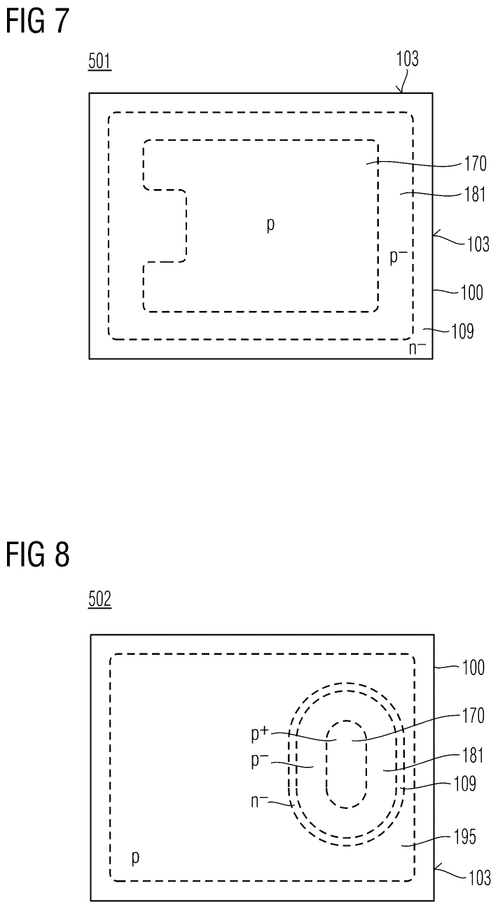

FIG. 7 shows a front side of a substrate 100 of a power semiconductor device with a p-conductive first doped region 170 formed in a central device region. The first doped region 170 may form an anode region of a high voltage semiconductor diode or a body region of an n-channel MOSFET. The cathode region of the high voltage semiconductor diode or the drain region of the n-channel MOSFET (not illustrated) are formed along the opposite back surface. In a peripheral device region surrounding the central device region, the weakly n-doped substrate base portion 109 brings the back-side potential along the outer lateral surface 103 to the front side. In an edge termination region separating the central device region and the peripheral device region, a junction termination region 181 extends outwardly from the first doped region 170 toward the lateral outer surface.

FIG. 8 shows a front side of a substrate 100 of a HVIC with a p-conductive first doped region 170 formed in a first voltage domain region and a second doped region 195 formed in a second voltage domain region of the substrate layer of a SOI configuration. The first voltage domain region is a first one of the low-side part and the high-side part of the HVIC. The second voltage domain region is the second one of the low-side part of the high-side part of the HVIC. In a device-internal termination region separating the first voltage domain region and the second voltage domain region, a junction termination region 181 extends outwardly from the first doped region 170 towards the second doped region 195.

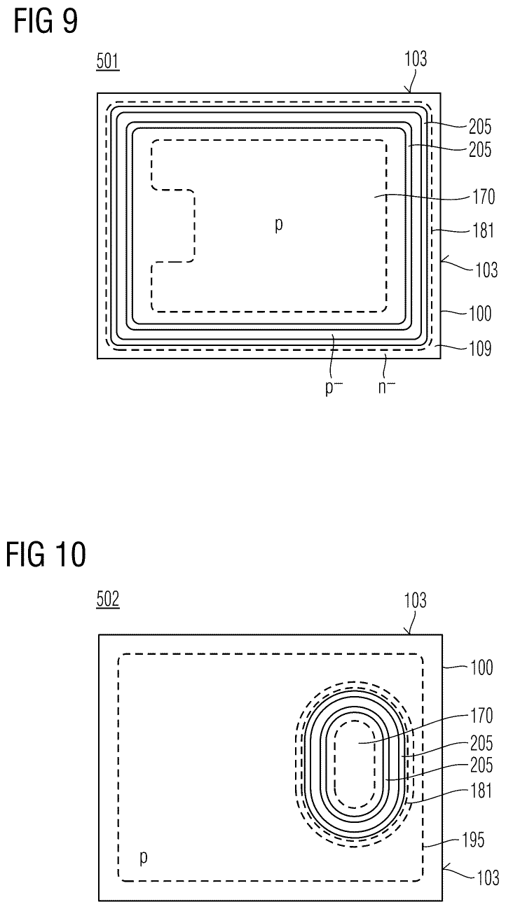

FIG. 9 supplements the power semiconductor device shown in FIG. 7 with a field plate structure that includes two ring-shaped field plate portions 205 formed in the edge termination region above the junction termination structure 181.

FIG. 10 supplements the HVIC shown in FIG. 8 with a field plate structure that includes two ring-shaped field plate portions 205 formed in the device-internal termination region above the junction termination structure 181.

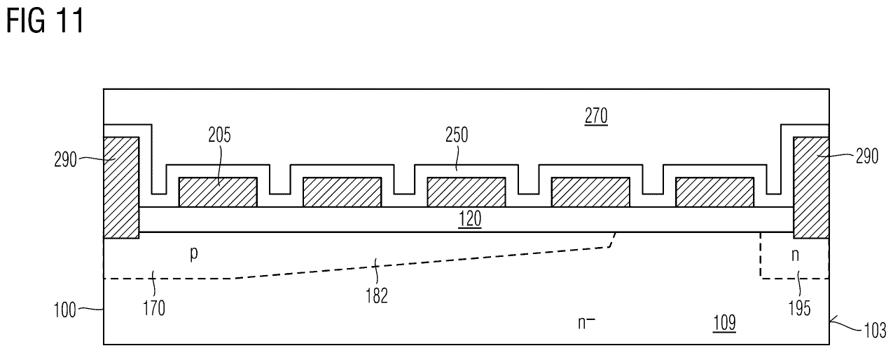

FIG. 11 shows another example of a power semiconductor device with a first doped region 170 formed in a central region of a substrate 100, a second doped region 195 formed in a peripheral region of the substrate 100 in direct contact with a lateral outer surface 103 of the substrate 100, and a variation of lateral doping region 182 extending in the lateral direction from the first doped region 170 towards the second doped region 195. A maximum vertical extent of the variation of lateral doping region 182 and the vertical extent of the first doping region may, for example, be equal. The maximum dopant concentration in the variation of lateral doping region 182 and the dopant concentration in the first doped region 170 may, for example, be equal.

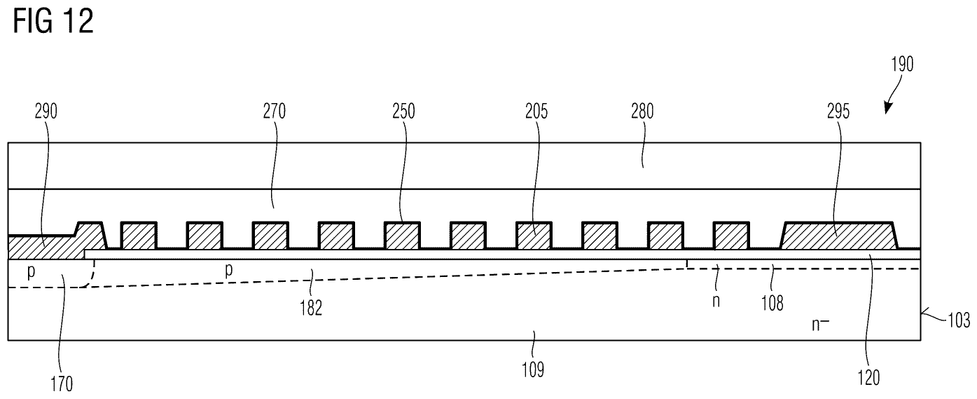

In FIG. 12, an n doped surface layer 108 formed directly below the main surface 101 extends from the variation of lateral doping region 182 to the lateral surface 103. A metal termination 295 is formed between the field plate structure 200 and the lateral outer surface 103 on the insulator layer 120.

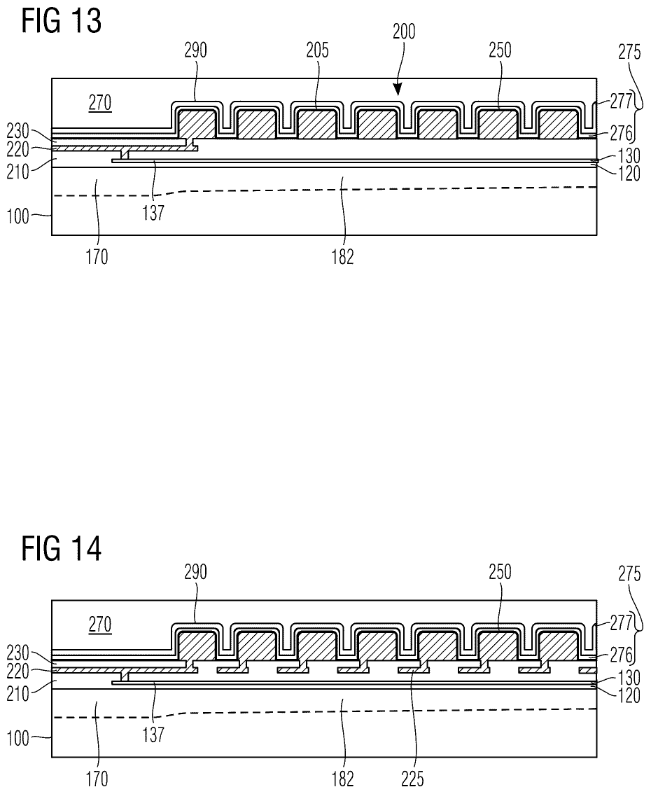

FIG. 13 and FIG. 14 show SOI devices. A substrate 100 includes a single-crystalline silicon layer forming the base of an SOI die. An insulator layer 120 is formed on the main surface 101 at a front side of the substrate 100. A semiconductor layer 130 is formed on the front side of the insulator layer 130. A first metallization structure 220 is formed directly on the first interlayer dielectric 210. A second interlayer dielectric 230 is formed directly on the first metallization structure 220, At least a portion of a field plate structure 200 with laterally separated field plate portions 205 is formed on the second interlayer dielectric 230.

A first contact structure 290 includes a portion of the first metallization structure 220, a through-via extending from the first metallization structure 220 through the first interlayer dielectric 210 to a doped device region 137 in the semiconductor layer 130, a metal pad formed on the second interlayer dielectric 230 and a through-via extending from the metal pad through the second interlayer dielectric 230 to the first metallization structure 220.

A charge shielding layer 250 is formed directly on the field plate portions 205, the portion of the contact structure 290 formed on the second interlayer dielectric 230, and sections of the second interlayer dielectric 230 between the field plate portions 205. A separation layer 275 is formed directly on the charge shielding layer 250 and separates the charge shielding layer 250 from a passivation layer 270 formed on the separation layer 275.

The separation layer 275 includes a silicon oxide layer 276 formed directly on the charge shielding layer 250 and a silicon nitride layer 277 formed directly on the silicon oxide layer. The separation layer 275 may contain silicon oxynitride at least along the interface between the silicon oxide layer 276 and the silicon nitride layer 277. The separation layer 275 forms a diffusion barrier that prevents ions to diffuse from the passivation layer 270 and the mold material into the charge shielding layer and beyond. By increasing the distance between the metal field plate portions 205 and the passivation layer 270, the separation layer 275 contributes to reducing the electric field in the passivation layer 270.

In FIG. 13, the field plate structure 200 is formed completely on the second interlayer dielectric 230.

In FIG. 14, each field plate portion 205 further includes a tile portion 225 formed from a portion of the first metallization structure 220 and a through-via extending from the portion formed on the second interlayer dielectric 230 through the second interlayer dielectric 230 to the tile portion 225. Each tile portion 225 completely spans a gap between the two portions of neighboring field plate portions 205 formed of the second interlayer dielectric 230.

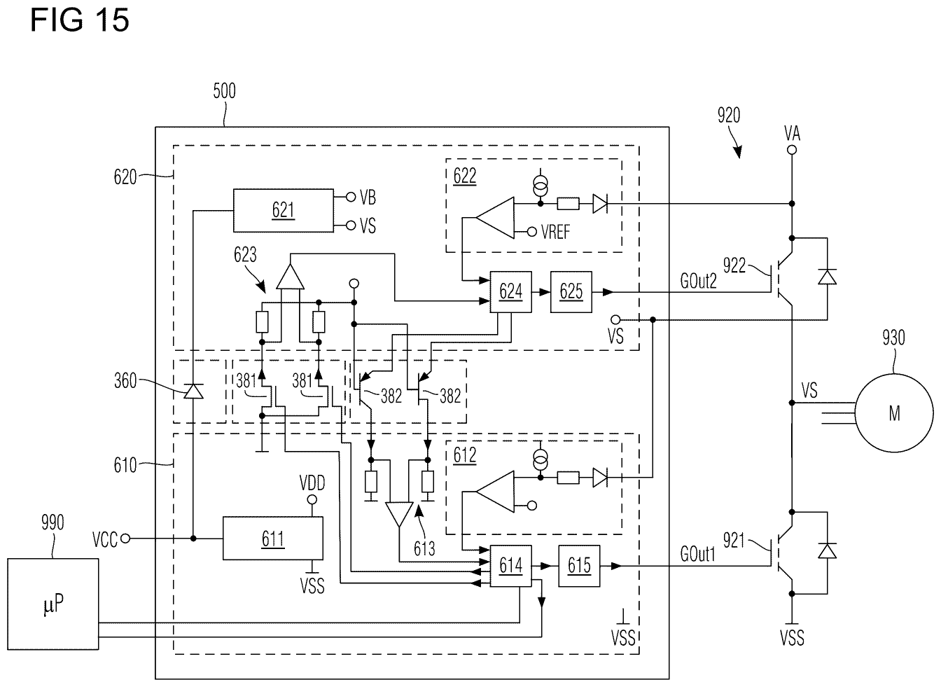

FIG. 15 shows a semiconductor device 500 configured as gate driver circuit. The gate driver circuit includes a high-side part 620 configured to drive a gate of a high-side switch 922 of a half bridge and a low-side part 610 configured to drive a gate of a low-side switch 921 of the half bridge. The semiconductor-on-insulator device 500 includes a high-side power supply circuit 621 to obtain a positive power supply voltage VB for the high-side part 620 (high-side supply potential VB), wherein a bootstrap diode 360 charges a bootstrap capacitor from an external supply voltage VCC. The positive power supply voltage VB for the high-side part 620 is referenced to a high-side reference potential VS, which corresponds to the potential of the switching node of a half bridge 920.

A high-side desaturation detection circuit 622 is connected to the supply potential VA of the half bridge 920, detects a desaturation of the high-side switch 922 of the half bridge 920, and outputs a high-side desaturation signal indicating whether a desaturation condition exists. A high-side receiver circuit 623 receives a differential gate control signal from two field effect transistors, e.g., n-channel MOSFETs 381 as described above and outputs a single-ended high-side gate control signal. A logic circuit 624 in the high-side part 620 receives the high-side desaturation signal and the high-side gate control signal. The logic circuit 624 in the high-side part 620 outputs a second gate-drive signal GOut2 in response to the high-side gate-control signal provided that the high-side desaturation signal does not indicate a desaturation condition. A high-side driver stage 625 may drive the second gate drive signal GOut2.

The logic circuit 624 in the high-side part further outputs a differential high-side data signal. Two pnp BJTs 382 as described above transmit the differential high-side data signal from the high-side part 620 to a low-side receiver circuit 613 in the low side part 610.

The low-side part 610 of the gate driver circuit includes a low-side power supply circuit 611 to obtain a positive power supply voltage VDD for the low-side part 610. The positive power supply voltage VDD for the low-side part 610 is referenced to the first reference potential VSS.

A low-side desaturation detection circuit 612 is connected to the output node of the half bridge 920, detects a desaturation of the low-side switch 921, and outputs a low-side desaturation signal indicating whether a desaturation condition exists. A low-side receiver circuit 613 receives a differential low-side data signal from the pnp BJTs 382 and outputs a single-ended low-side data signal. A logic circuit 614 in the low-side part 610 receives the low-side data signal, the low-side desaturation signal, and a low-side gate-control signal from an external source like a processor 990. The logic circuit 614 in the low-side part 610 outputs a first gate-drive signal GOut1 in response to the low-side gate-control signal provided that none of the low-side desaturation signal and the low-side data signal indicates a desaturation condition. A low-side driver stage 615 drives the first gate drive signal GOut1.

The logic circuit 614 in the low-side part 610 further outputs a differential gate control signal. The two n-channel MOSFETs 381 transmit the differential gate control signal from the low-side part 610 to the high-side part 620. An inductive load 930 is electrically connected between the switching nodes of two half bridges 920.

The n-channel MOSFETs 381 and pnp BJTs 382 having any of the configurations of the present embodiments improve the signal transfer between the low-side part 610 and the high-side part 620, reduce the leakage current between high-side part 620 and low-side part 610, can be formed more compact and can reduce switching time and therefore improve the performance of the half bridge 920 by allowing higher switching frequencies.

Although specific examples have been illustrated and described herein, it will be appreciated by those of ordinary skill in the art that a variety of alternate and/or equivalent implementations may be substituted for the drain current specific examples shown and described without departing from the scope of the present invention. This application is intended to cover any adaptations or variations of the specific examples discussed herein. Therefore, it is intended that this invention be limited only by the claims and the equivalents thereof.

It should be noted that the semiconductor device including its preferred embodiments as outlined in the present document may be used stand-alone or in combination with the other semiconductor devices disclosed in this document. In addition, the features outlined in the context of a semiconductor device are also applicable to a corresponding method, and vice versa. Furthermore, all aspects of the methods and semiconductor devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A semiconductor device, comprising:
a substrate having a background doping of a first conductivity type and comprising a first doped region of a second conductivity type complementary to the first conductivity type;
an insulator layer on a main surface of the substrate; and
a field plate structure on the insulator layer between the first doped region and an edge structure, wherein the field plate structure has a high-resistive and/or semi-insulating connection with at least one non-floating conductive structure.

2. The semiconductor device of claim 1,
wherein the non-floating conductive structure includes a contact structure,
wherein the contact structure forms an ohmic contact with one of the first doped region and a second doped region, and
wherein the second doped region forms part of the edge structure.

3. The semiconductor device of claim 1,
wherein the non-floating conductive structure includes a contact structure,
wherein the contact structure forms an ohmic contact with a first doped device region and/or a second doped device region of a semiconductor layer on the insulator layer.

4. The semiconductor device of claim 1,
wherein the high-resistive and/or semi-insulating connection comprises a charge shielding layer in direct contact with the field plate structure and the non-floating contact structure.

5. The semiconductor device of claim 4,
wherein the charge shielding layer is formed directly on the field plate structure.

6. The semiconductor device of claim 4, further comprising:
an insulating passivation layer on the charge shielding layer.

7. The semiconductor device of claim 6, further comprising:
a separation layer separating the charge shielding layer and the passivation layer.

8. The semiconductor device of claim 4,
wherein the field plate structure comprises a metal portion, and
wherein the charge shielding layer is formed directly on the metal portion.

9. The semiconductor device of claim 4,
wherein the field plate structure comprises a polysilicon portion formed from doped polycrystalline silicon, and
wherein the charge shielding layer is formed directly on the polysilicon portion.

10. The semiconductor device of claim 4,
wherein the field plate structure comprises a polycrystalline portion at a distance from the main surface and a metal portion in direct contact with the polycrystalline portion at a side of the polycrystalline portion opposite to the substrate, and
wherein the charge shielding layer is formed directly on the metal portion.

11. The semiconductor device of claim 1, further comprising:
a voltage transition structure in the substrate between the first doped region and the edge structure,
wherein the voltage transition structure is configured to reduce a maximum electric field in the substrate when a voltage is present between the first doped region and the edge structure.

12. The semiconductor device of claim 11,
wherein the voltage transition structure laterally surrounds the first doped region.

13. The semiconductor device of claim 1,
wherein the field plate structure laterally surrounds the first doped region.

14. The semiconductor device of claim 1,
wherein the edge structure comprises a lateral outer surface of the substrate.

15. The semiconductor device of claim 1, further comprising:
a semiconductor layer on the insulator layer; and
a first interlayer dielectric on the semiconductor layer,
wherein the field plate structure is formed on the first interlayer dielectric.

16. The semiconductor device of claim 15, further comprising:
a first metallization structure directly on the first interlayer dielectric; and
a second interlayer dielectric directly on the first metallization structure,
wherein the field plate structure comprises a first portion formed from a field portion of the first metallization structure and a second portion formed on the second interlayer dielectric.

17. The semiconductor device of claim 16,
wherein the field plate structure further comprises a plurality of laterally separated field plate portions,
wherein the first metallization layer comprises a plurality of laterally separated tile portions, and
wherein each tile portion of the first metallization layer is electrically connected with at least one of the field plate portions.

18. The semiconductor device of claim 17,
wherein the tile portions are formed in gaps between the field plate portions.
